(19) United States
(12) Patent Application Publication
(10) Pub. No.: US 2025/0191909 A1
(43) Pub. Date: Jun. 12, 2025

(54) UNIFORM GAPFILL DEPOSITION ON SEMICONDUCTOR SUBSTRATES WITH VARYING GEOMETRIES

(71) Applicant: Applied Materials, Inc., Santa Clara, CA (US)

(72) Inventors: Bharati Neelamraju, Sunnyvale, CA (US); Prashant Kumar Kulshreshtha, San Jose, CA (US)

(73) Assignee: Applied Materials, Inc., Santa Clara, CA (US)

(21) Appl. No.: 18/534,061

(22) Filed: Dec. 8, 2023

(51) Int. Cl. H01L 21/02; C23C 16/02; C23C 16/04; C23C 16/26; C23C 16/505; H01J 37/32

(52) U.S. Cl. CPC H01L 21/02274; C23C 16/0236; C23C 16/045; C23C 16/26; C23C 16/505; H01J 37/32449; H01L 21/02115; H01L 21/0228; H01J 37/32082; H01J 2237/3321; H01J 2237/334

(57) ABSTRACT

A gapfill precursor may be provided to a processing chamber for filling features in a semiconductor structure. The features may have different critical dimensions. An etchant configured to etch the gapfill material may also be provided with the precursor. A plasma power in the chamber may have a duty cycle of a first RF power provided during a first time duration and a second RF power provided during a second time duration, where the second RF power is less than the first RF power. The RF power levels may be selected such that the gapfill material is deposited in the bottom of the features while being etched at a top of the features during the first time, and deposited on both the bottom and top of the features during the second time, where the features having different CDs finish the gapfill process at about the same time.

### TECHNICAL FIELD

This disclosure generally describes plasma system fabrication processes. More specifically, this disclosure describes methodologies for plasma system fabrication processes involving samples with multiple CDs.

### BACKGROUND

Integrated circuits are made possible by processes which produce intricately patterned material layers on substrate surfaces. Producing patterned material on a substrate requires controlled methods of formation and removal of exposed material. As device sizes continue to shrink, material formation may affect subsequent operations. For example, in gap filling operations a material may be formed or deposited to fill a trench or other features formed on a semiconductor substrate. Some devices can include trenches or features of varying dimensions such as trenches with varying widths. For such devices, it may be necessary to develop special methodologies or techniques to form uniform deposited layers.

Thus, there is a need for improved systems and methods that can be used to produce high quality devices and structures. These and other needs are addressed by the present technology.

### SUMMARY

In some embodiments, a method may include providing a precursor to a semiconductor processing chamber. The precursor may include a gapfill material for filling features in a semiconductor structure, and the features in the semiconductor structure may have different critical dimensions (CDs). The method may also include providing an etchant to the semiconductor processing chamber with the precursor, where the etchant may be configured to etch the gapfill material. The method may additionally include applying a radio-frequency (RF) power to the processing chamber to perform a deposition process. The RF power may be provided according to a duty cycle that includes a first RF power provided during a first time duration and a second RF power provided during a second time duration, where the second RF power is less than the first RF power.

In some embodiments, a method may include providing a precursor to a semiconductor processing chamber. The precursor may include a gapfill material for filling features in a semiconductor structure, and the features in the semiconductor structure may have different critical dimensions (CDs). The method may also include providing an etchant to the semiconductor processing chamber with the precursor, where the etchant may be configured to etch the gapfill material. The method may additionally include applying a radio-frequency (RF) power to the processing chamber to perform a deposition process. The RF power may be provided according to a duty cycle that includes a first RF power provided during a first time duration during which the gapfill material is deposited in a bottom portion of the features while the gapfill material is etched at a top portion of the features; and a second RF power provided during a second time duration during which the gapfill material is deposited in the bottom portion of the features at the top portion of the features.

In some embodiments, a method may include providing a precursor to a semiconductor processing chamber. The precursor may include a gapfill material for filling features in a semiconductor structure, and the features in the semiconductor structure may have different critical dimensions (CDs). The method may also include providing an etchant to the semiconductor processing chamber with the precursor, where the etchant may be configured to etch the gapfill material. The method may also include applying a radio-frequency (RF) power to the processing chamber to perform a deposition process. The RF power may be provided according to a duty cycle that includes a first RF power provided during a first time duration, and a second RF power provided during a second time duration. The duty cycle may cause the features in the semiconductor structure having different CDs to finish the gapfill process at approximately a same time, and an overburden of the gapfill material on top of the semiconductor structure may be substantially uniform.

In any embodiments, any and/or all of the following features may be implemented in any combination and without limitation. The semiconductor structure may include a memory structure that includes more than 100 alternating oxide/nitride layers. The first time duration may be greater than 50% of the period of the duty cycle. The precursor may include carbon, tungsten, or amorphous silicon. A co-flow rate provided to the processing chamber while performing the deposition process may be provided according to the duty cycle that include a first co-flow rate during the first time duration and a second co-flow rate during the second time duration, where the second co-flow rate may be greater than the first co-flow rate. Applying the first RF power may include etching tops of pillars of the semiconductor structure while depositing the material on sidewall formations of trenches of the patterned sample. Applying the second RF power may include depositing the material onto tops of pillars of the patterned sample while depositing the material on sidewall formations of trenches of the patterned sample. The features in the semiconductor structure may include memory holes with a CD that is less than 150 nm. The features in the semiconductor structure may include slits with a CD that is grater than 350 nm. The features may include first features and second features, and the second features may have a CD that is at least twice as large as a CD of the first features. The first RF power may result in a higher deposition rate in the first features and a lower deposition rate in the second features. The second RF power may result in a similar deposition rate in the first features and the second features. The first RF power may be selected from a first data set for a first feature size and from a second data set from a second feature size, where the first data set and the second data set may represent deposition rates over an RF power range, and the first RF power may correspond to a similar deposition rate in both the first data set and the second data set. The second RF power may be selected from a first data set for a first feature size and a second data set from a second feature size, where the first data set and the second data set may represent deposition rates over an RF power range, and the second RF power may correspond to a low deposition rate in the first data set and to a higher deposition rate in the second data set. The duty cycle may causes the features in the semiconductor structure having different CDs to finish the gapfill process without voids in top halves of the features. The duty cycle may cause the features in the semiconductor structure having different CDs to finish the gapfill process to form voids in bottom halves of the features. The duty cycle may include a square wave that oscillates between the first RF power and the second RF power, and the first RF power may be between 50 and 90% of each cycle. The first RF power may be between about 800 W and about 2000 W, and the second RF power may be between about 100 W and about 500 W.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a schematic cross-sectional view of an exemplary processing chamber according to some embodiments of the present technology.

FIG. 2 shows a schematic cross-sectional view of a patterned sample with regions of different CDs, according to some embodiments.

FIG. 3 is a graph that shows a dependence of sidewall deposition rate for a trench on radio-frequency power and co-flow rate of a deposition process, according to some embodiments.

FIG. 4 is a graph that shows a dependence of sidewall deposition rate for a 400 nm diameter trench on radio-frequency power and co-flow rate of a deposition process, according to some embodiments.

FIG. 5 is a graph of a duty cycle for a gapfill deposition process, according to some embodiments.

FIG. 6 is a flow chart of an example of a process for depositing material onto a patterned substrate according to some embodiments.

FIG. 7 illustrates an example computer system, in which various embodiments may be implemented.

### DETAILED DESCRIPTION OF THE INVENTION

Certain aspects and examples of the present disclosure relate to systems and techniques for depositing layers on patterned samples having features of varying dimensions. The varying dimensions can be critical dimensions (CDs). A critical dimension can be a minimum size of a feature that impacts electrical properties of a device. Devices can have multiple CDs. For example, a patterned wafer can include stacks of NAND memory elements. One CD of the patterned wafer can be associated with a width of trenches that separate stacks. Another CD can be associated with patterned holes or slits for vias or for making electrical contact with multiple NAND memory elements in a stack or in multiple stacks. The patterned holes can have different dimensions and shapes compared to the trenches. A single gapfill material can be deposited in the pattern holes and trenches. Forming a uniform layer of gapfill material on the patterned wafer can be challenging due to variation in sizes and shapes of the pattern holes and trenches.

As an example, a patterned sample can have trenches of different dimensions. In a first region of the patterned sample, smaller trenches can have dimensions of 100 nm and a second region of the patterned sample can include larger trenches with dimensions of 300 nm. If a single sidewall deposition rate is used, the trenches can fill or experience sidewall pinch-off at different times. For example, with a sidewall deposition rate of 10 nm/minute, the smaller trenches can experience sidewall pinch-off after 5 minutes (since sidewall growth occurs on both ends of the trench). At the same sidewall deposition rate, the larger trenches can experience sidewall pinch-off after 15 minutes. Preferably, to form a uniform overgrowth layer above pillars and trenches, sidewall pinch-off should occur simultaneously for all trenches regardless of size. Thus, preferably, trenches of varying CDs can involve varying deposition rates: trenches with larger diameters can have higher deposition rates than trenches with smaller diameters.

Further, in some examples, trenches with large diameters can experience pinch-offs at multiple locations relative to the large trench. For example, a large trench can experience side-wall pinch-off at depth and overgrowth pinch-off above the trench, leading to an unwanted void in the trench. The unwanted void can affect uniformity of successive deposition processes on the device and have a detrimental effect on device performance.

A deposition process can include a methodology that forms a uniform overgrowth layer and avoids void formation despite a variation in CDs of a patterned device. The methodology can involve an application of a time dependent duty cycle during the deposition process. The time dependent duty cycle can include parameters that can be optimized based on the geometries of the patterned device. The parameters can include frequency of the duty cycle, multiple radio-frequency (RF) power values associated with a plasma deposition process, co-flow rate of an etchant and precursor for the plasma deposition process, types of etchants, types of precursors, or application times for the multiple RF power values. Application of the time dependent duty cycle can promote sidewall growth for each trench or hole with deposition rates that depend on a CD associated with each trench or hole. The time dependent duty cycle can also discourage overgrowth pinch-off by etching overgrowth during a portion of the duty cycle without interrupting sidewall growth.

After describing general aspects of a chamber according to some embodiments of the present technology in which plasma processing operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

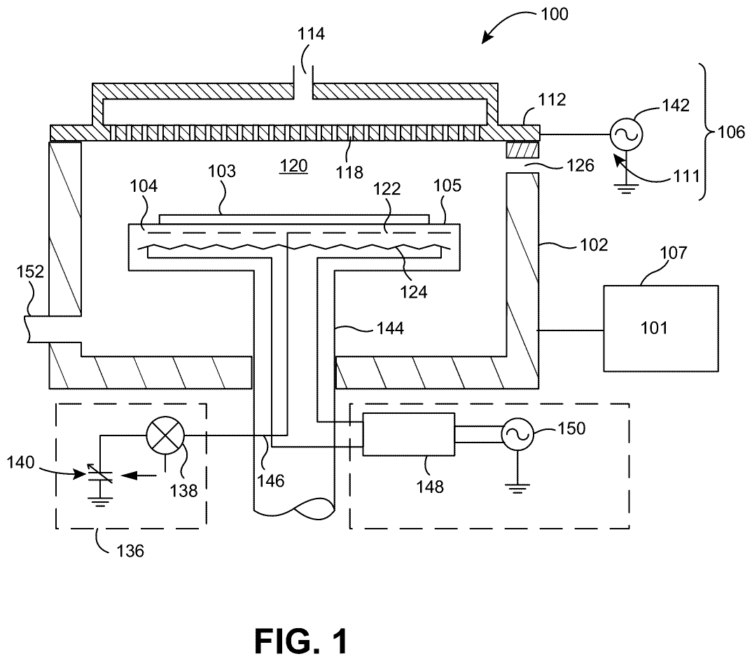

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, along a vertical axis, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the tuning circuit 136 in a closed loop. A set point for current or voltage, depending on the type of sensor used, may be installed in each sensor, and the sensor may be provided with control software that determines an adjustment to the electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

Processing chamber 100 may be utilized in some embodiments of the present technology for processing methods that may include bottom-up deposition of materials for semiconductor structures. It is to be understood that the chamber described is not to be considered limiting, and any chamber that may be configured to perform operations as described may be similarly used.

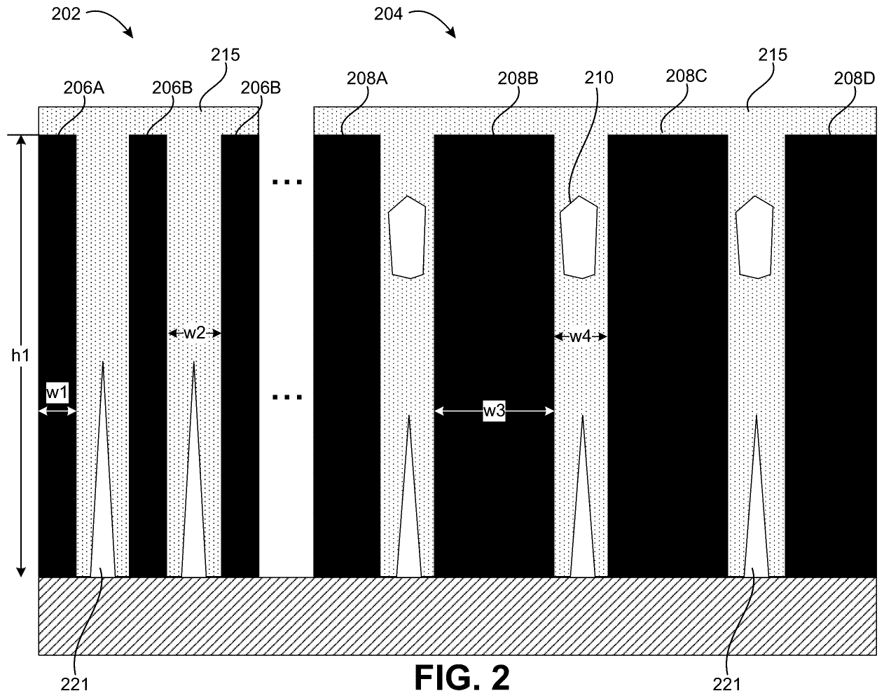

FIG. 2 shows a schematic cross-sectional view of a patterned sample with regions of different CDs, according to some embodiments. The patterned sample can include a first region 202 and a second region 204. The second region 204 can include features with at least one CD that is different from the CDs associated with features included in the first region 202 of the patterned sample. The first region 202 can include pillars such as pillar 206A, pillar 206B, and pillar 206C. Although three pillars are shown in first region 202, the first region 202 can include any number of pillars. Each of the pillars in the first region 202 can be formed from multiple alternating deposited layers. The alternating deposited layers can be deposited layers in a memory stack structure such as a NAND structure. For example, the alternating deposited layers can include alternating layers of silicon oxide and silicon nitride.

The multiple alternating deposited layers in the first region 202 can be etched to form the pillars, including pillar 206A, pillar 206B, and pillar 206C. An etch region between adjacent pillars can form a trench. Each pillar can have a width, w1, and a height, h1. Each trench can have a width, w2, and the height, h1. The trenches can be deep trenches (e.g., h1>>w2). For example, the width of a trench, w2, can be about 100 nm. For example, each trench can have a width, w2, of between about 10 nm and about 30 nm, between about 30 nm and about 50 nm, between about 50 nm and about 70 nm, between about 70 nm and about 90 nm, between about 90 nm and about 110 nm, between about 110 nm and about 130 nm, between about 130 nm and about 150 nm, between about 150 nm and about 170 nm, between about 170 nm and about 190 nm, between about 190 nm and about 210 nm, between about 210 nm and about 230 nm, between about 230 nm and about 250 nm, between about 250 nm and about 270 nm, between about 270 nm and about 290 nm, between about 290 nm and about 310 nm, between about 310 nm and about 330 nm, and/or between about 330 nm and about 350 nm. The width of each trench may also be any combination of these ranges (e.g., between about 250 nm and about 300 nm). The width of each trench may also be any specific value within these ranges (e.g., about 160 nm).

The pillars in region 202 can have a same or different width, w1, than the width, w2, of the trenches in region 202. For example, the width, w1, of a pillar in region 202 can be about 140 nm. For example, each pillar in region 202 can have a width of between about 10 nm and about 30 nm, between about 30 nm and about 50 nm, between about 50 nm and about 70 nm, between about 70 nm and about 90 nm, between about 90 nm and about 110 nm, between about 110 nm and about 130 nm, between about 130 nm and about 150 nm, between about 150 nm and about 170 nm, between about 170 nm and about 190 nm, between about 190 nm and about 210 nm, between about 210 nm and about 230 nm, between about 230 nm and about 250 nm, between about 250 nm and about 270 nm, between about 270 nm and about 290 nm, between about 290 nm and about 310 nm, between about 310 nm and about 330 nm, and/or between about 330 nm and about 350 nm. The width of each pillar in region 202 may also be any combination of these ranges (e.g., between about 100 nm and about 250 nm). The width of each pillar in region 202 may also be any specific value within these ranges (e.g., about 140 nm).

The height, h1, of a trench in the first region 202 can be about 10 microns. For example, each trench can have a height of between about 1 microns and about 3 microns, between about 3 microns and about 5 microns, between about 5 microns and about 7 microns, between about 7 microns and about 9 microns, between about 9 microns and about 11 microns, between about 11 microns and about 13 microns, between about 13 microns and about 15 microns, between about 15 microns and about 17 microns, between about 17 microns and about 19 microns, between about 19 microns and about 21 microns, between about 21 microns and about 23 microns, between about 23 microns and about 25 microns, between about 25 microns and about 27 microns, between about 27 microns and about 29 microns, between about 29 microns and about 31 microns, between about 31 microns and about 33 microns, and/or between about 33 microns and about 35 microns. The height of each trench may also be any combination of these ranges (e.g., between about 20 microns and about 35 microns). The height of each trench may also be any specific value within these ranges (e.g., about 30 microns). In some examples, the height of each trench can be designed to be a multiplicative factor of the width of each trench (e.g., h1=50*w2, h1=100*w2, etc.). The height of the pillars in region 202 can be the same as the height of the trenches in region 202.

The second region 204 can include wide pillars such as wide pillar 208A, wide pillar 208B, wide pillar 208C, and wide pillar 208D. Although four wide pillars are shown in second region 204, the second region 204 can include any number of wide pillars. Each of the wide pillars in the second region 204 can form vias or contacts for making electrical contact with portions of the patterned sample.

Layer(s) in the second region 204 can be etched to form the wide pillars, including wide pillar 208A, wide pillar 208B, wide pillar 206C, and wide pillar 206D. An etch region between adjacent wide pillars can form a wide trench. Each wide pillar can have a width, w3, and a height, h1. Each wide trench can have a width, w4, and the height, h1. The wide trenches can be deep trenches (e.g., h1>>w4). The width of a wide trench, w4, of the second region 204 can be larger than a width, w2, of each trench in the first region 202 (e.g., w4>w2). For example, the width of a wide trench, w3, can be about 250 nm. For example, each wide trench can have a width of between about 90 nm and about 110 nm, between about 110 nm and about 130 nm, between about 130 nm and about 150 nm, between about 150 nm and about 170 nm, between about 170 nm and about 190 nm, between about 190 nm and about 210 nm, between about 210 nm and about 230 nm, between about 230 nm and about 250 nm, between about 250 nm and about 270 nm, between about 270 nm and about 290 nm, between about 290 nm and about 310 nm, between about 310 nm and about 330 nm, between about 330 nm and about 350 nm, between about 350 nm and about 370 nm, between about 370 nm and about 390 nm, between about 390 nm and about 410 nm, between about 410 nm and about 430 nm, and/or between about 430 nm and about 450 nm. The width of each wide trench may also be any combination of these ranges (e.g., between about 190 nm and about 400 nm). The width of each wide trench may also be any specific value within these ranges (e.g., about 300 nm).

The wide pillars in region 204 can have a same or different width, w3, than the width, w4, of the wide trenches in region 204. For example, the width, w3, of a wide pillar in region 204 can be about 240 nm. For example, each wide pillar can have a width of between about 90 nm and about 110 nm, between about 110 nm and about 130 nm, between about 130 nm and about 150 nm, between about 150 nm and about 170 nm, between about 170 nm and about 190 nm, between about 190 nm and about 210 nm, between about 210 nm and about 230 nm, between about 230 nm and about 250 nm, between about 250 nm and about 270 nm, between about 270 nm and about 290 nm, between about 290 nm and about 310 nm, between about 310 nm and about 330 nm, between about 330 nm and about 350 nm, between about 350 nm and about 370 nm, between about 370 nm and about 390 nm, between about 390 nm and about 410 nm, between about 410 nm and about 430 nm, and/or between about 430 nm and about 450 nm. The width of each wide pillar may also be any combination of these ranges (e.g., between about 200 nm and about 300 nm). The width of each wide pillar may also be any specific value within these ranges (e.g., about 250 nm). The width, w3, of the wide pillars in the second region 204 can be larger than the width, w1, of the pillars in the first region 202.

Each of the trenches, slits, holes, or other features etched into the layers of the substrate may be filled with a gapfill material using a gapfill process. As described above, voids such as void 210 can form within each wide trench of the second region 204 during the gapfill process. Wider pillars and/or wider trenches can lead to void formation. Trenches and/or pillars with large diameters can experience pinch-offs at multiple locations relative to the trench. For example, a large trench can experience side-wall pinch-off at depth and overgrowth pinch-off above the trench, leading to an unwanted void in the trench. The unwanted void can affect uniformity of successive deposition processes on the device and have a detrimental effect on device performance.

The patterned sample with the multiple regions can be incorporated in a process, such as a gapfill deposition process. For example, the patterned sample can be placed in a process chamber such as process chamber 100 from FIG. 1 and trenches or patterned holes of the patterned sample can be filled by a gapfill material 215 during a plasma-enhanced chemical vapor deposition PECVD process. During the PECVD process, a methodology can be employed that forms a uniform overgrowth layer and avoids void formation despite a variation in CDs of a patterned device. The methodology can involve an application of a time-dependent duty cycle during the deposition process. The time dependent duty cycle can include parameters that can be optimized based on the geometry of the patterned device. The parameters can include frequency of the duty cycle, multiple radio-frequency (RF) power values associated with a plasma deposition process, co-flow rates of an etchants and precursors for the plasma deposition process, types of etchants, types of precursors, and/or application times for the multiple RF power values. Application of the time-dependent duty cycle can promote sidewall growth for each trench or hole with deposition rates that depend on a CD associated with each trench or hole. The time dependent duty cycle can also discourage overgrowth pinch-off by etching overgrowth during a portion of the duty cycle without interrupting sidewall growth.

By way of example, each feature in the first region 202 may instead be a memory hole in a memory device stack having a cylindrical shape with a 100 nm to 120 nm critical dimension or diameter. For example, these holes may be formed in alternating oxide/nitride layers for a NAND memory structure. The features in the second region 204 may be contact holes also available in the memory stack. The second region 204 may also include through-hole vias extensions to the memory cell for landing pads, and other features of the memory device. Therefore, the memory structure may include many different sizes of holes having different diameters and critical dimensions. As described above, the first region 202 and/or the second region 204 may include slits or other elongated trenches in the memory devices that also have varying widths. During the manufacturing process, each of these trenches, slits, and/or holes (collectively described herein as “features”) may be filled with a gapfill material. When forming the gapfill material in each of these features, it may be beneficial to form an overgrowth or overburden layer having an equal or substantially uniform height above the features in the contact hole area, the trench area, the memory hole area, and so forth, across the semiconductor structure. As illustrated in FIG. 2, the gapfill operation may unintentionally generate voids, seams, or gaps near the tops of the features. As described above, these voids or gaps may form when pinchoff occurs in the feature during the gapfill process. However, to avoid the voids, gapfill processes in smaller, deeper holes need to use a slower deposition rate. But since the semiconductor structure in FIG. 2 also includes relatively large features, a slow deposition rate would take far too long to gapfill the larger features. The resulting voids 210 are unwanted and can have negative effects on subsequent processing stages.

The embodiments described herein solve these and other technical problems for gapfill operations where features have different critical dimensions, and/or other geometries. These techniques utilize the characteristics of each of the features themselves to define the growth rate of the sidewall during the gapfill. For example, for a feature having a wider CD, the flux of material flowing into the feature will be greater and allow the larger feature to gapfill in about the same amount time as the relatively smaller features in the structure. In order to vary the flux based on feature size on the same substrate, some embodiments may combine an etchant with a deposition precursor at the same time during the gapfill process. For example, a carbon gapfill may be etched by material such as carbon dioxide, hydrogen, ammonia, etc. These etchant materials may be provided to the processing chamber along with the carbon precursors for the gapfill process. By varying the RF power, these techniques may limit the deposition that takes place at the top of the feature relative to the bottom of the feature where a higher deposition rate may be maintained. For example, by etching at the top of the features, the bottom of the features may fill until the pinch off occurs leaving an acceptable voided 221 at the bottom of the future. At that point, “blanket” growth may occur where the bottom portion of the features fill uniformly to avoid the voids 210 later at the top that can be problematic. This pinch off may occur at a depth of about 400 nm below the surface of the structure or the top of the feature.

In order to etch the gapfill material in the top portion of the features and allow the blanket growth to occur after pinchoff, the embodiments described herein may also adjust the power level of the RF power provided to the deposition plasma in the processing chamber. For example, the plasma condition can heavily influence the depth to which the etch occurs. Conventionally, a higher level of RF power generally was thought to increase the level of deposition relative to the amount of etching the takes place. Conversely, a lower RF power was believed to generally decrease the level of deposition. However, it has been discovered that a higher level of RF power actually results in a greater amount of etching that takes place at the top of the features, thereby allowing more flux to enter the features such that deposition can occur throughout the depth of the features. For example, the etch process results in the disassociation of more material within the feature, which allows for higher deposition rates towards the bottom of the feature relative to the top. The etch ions have a relatively short lifetime, and once they are within the feature, the etch ions tend to recombine. In contrast, certain carbon precursor chemistries can increase the radicals present in the features. Temperatures can be maintained that keep these radicals around 95% efficient when attaching to the sidewalls of the future for deposition.

In order to identify process conditions that generate a high etch rate at the top of large features with a high deposition rate at the lower portion of these features, data may be used based on the different geometries of the features on the substrate. For example, when gapfilling relatively small features (e.g., about 100 nm) at the same time as relatively large features (e.g., about 400 nm), a single processing condition may not be sufficient. Instead, multiple process conditions may be identified, and the process may then alternate between these processing conditions for an optimal result. For example, a first process condition may be identified that produces a rapid etch at the top of the features, and the second process condition may also be identified that produces a high deposition rate within the features. The process may then alternate (or “duty cycle”) between these process conditions. This can result in a balanced process that maintains the etch at the top of the features just enough to prevent voids, while not slowing down the gapfill process throughout the depth of the features. For example, some embodiments may alternate between a high-deposition rate condition and a low-deposition rate condition at the top of the features. This allows, for example, carbon gapfill material time to attach while the hydrogen etch activity is slowed down in the depth of the feature, also while maintaining the etch condition at the top.

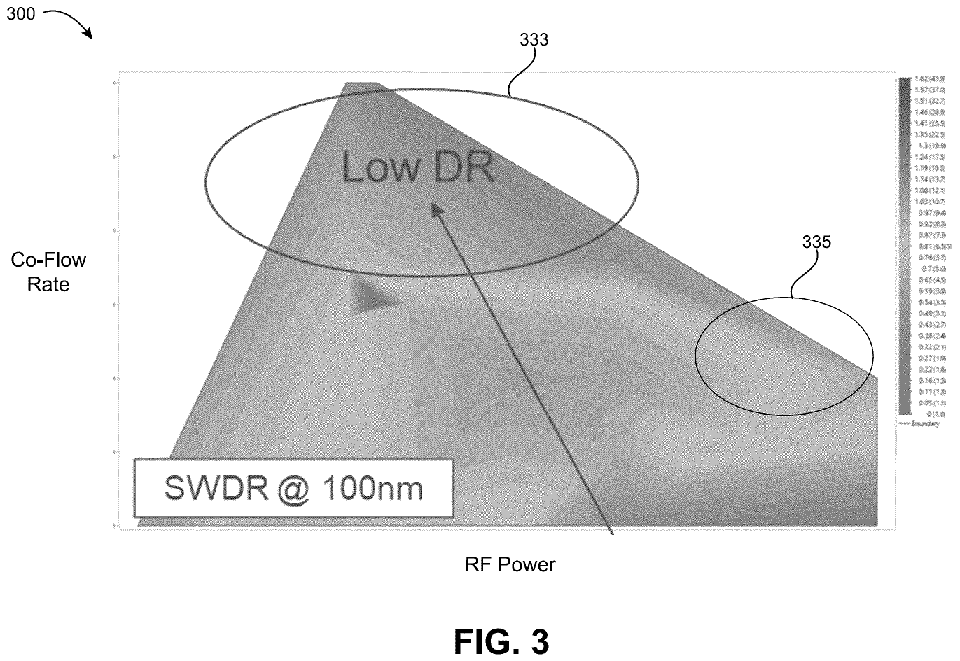

FIG. 3 is a graph 300 that shows a dependence of sidewall deposition rate at a depth of 100 nm in a trench as a function of radio-frequency (RF) power and co-flow rate of a deposition process, according to some embodiments. Co-flow rate can describe a combined flow rate of a combination of etch gases and precursors used during the deposition process. In some examples, The deposition process can be a PECVD process for depositing gapfill material into the trench. The gapfill material can be carbon. The etching gases can be gases that etch carbon, such as carbon dioxide, hydrogen, ammonia, nitrous oxide, oxygen, etc. The precursors can be precursors for carbon. The graph indicates a couple of regimes for high sidewall deposition rates for an etch gas of hydrogen. The deposition rates of carbon for this trench width can be relatively high for moderate values of both the co-flow rate and RF power. Also, high deposition rates can be found at very high RF power and very low co-flow rates. Low deposition rates occur for moderate RF power values and very high co-flow rates. Note that relatively low deposition rates can be found for very high values of RF power and low to moderate values for the co-flow rate.

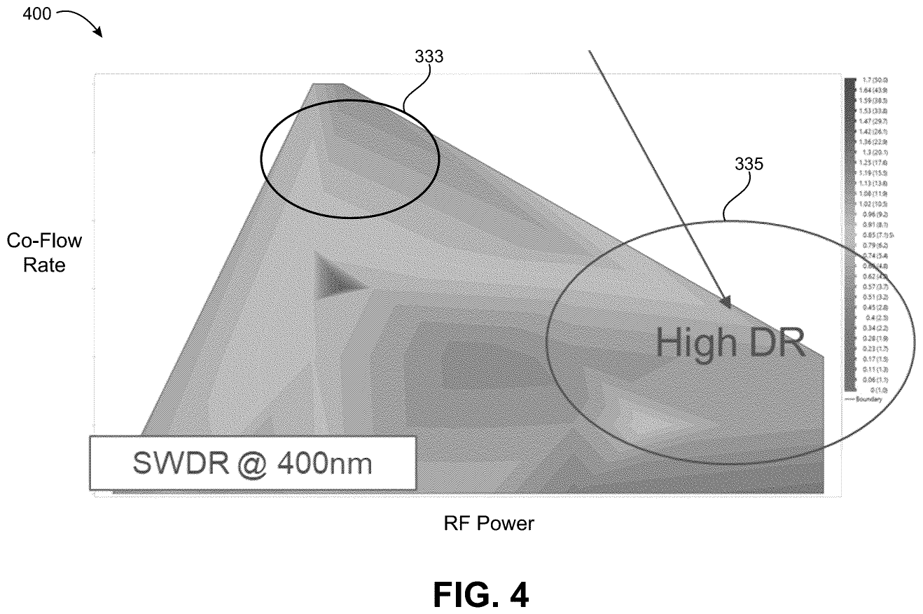

FIG. 4 is a graph 400 that shows a dependence of sidewall deposition at a depth of 400 nm in a trench as a function of RF power and the co-flow rate of a deposition process, according to some embodiments. As described above, the co-flow rate can describe a combined flow rate of a combination of etch gases and precursors used during the deposition process. In some examples, The deposition process can be a PECVD process for depositing gapfill material into the trench. The gapfill material can be carbon. The etching gases can be gases that etch carbon, such as carbon dioxide, hydrogen, ammonia, nitrous oxide, oxygen, etc. The precursors can be precursors for carbon. The graph indicates several regimes for high sidewall deposition rates for an etch gas of hydrogen. The deposition rates of carbon for this trench width can be relatively high for moderate values of both the co-flow rate and RF power. Also, high deposition rates can be found at very high RF power and very low co-flow rates. In contrast to the graph 300 for the 100 nm diameter trench, high deposition rates can also be found for very high values of RF power and low to moderate values for the co-flow rate.

Using data such as those found in graph 300 and graph 400, it is possible to identify a regime that may simultaneously provide a low deposition condition for smaller features while providing a high deposition rate for larger features. For example, region 333 in graph 300 and graph 400 illustrates a low deposition region for both large and small features. In contrast, region 335 illustrates a low deposition region for small features, while simultaneously providing a high deposition region for large features. Identifying these types of regions can then provide the operating conditions between which the process may duty cycle to balance etching and deposition and maintain a consistent gapfill across large and small features.

For example, a co-flow rate for the deposition process may be selected as a process parameter. A first data set may be provided for a first feature size, and a second data set may be provided for a second feature size. The graph 300 may be a first data set represents deposition rates over an RF power range. Graph 400 may be a second data set that represents deposition rates over the same RF power range. A second power to be used during the second time duration of the duty cycle may be selected such that the RF power corresponds to a relatively low (and possibly similar) deposition rate in the data sets of both graphs. A first power to be used during the second time duration of the duty cycle may be selected such that the deposition rate for the smaller features is lower than the deposition rate for the larger features.

Note that graph 300 and graph 400 are provided only by way of example and are not meant to be limiting. These data represent a specific type of deposition precursor and/or etching combination at a specific temperature. Other precursors or agents may be more effective at other temperatures and may reveal entirely different regions where the low/high deposition combination may be most effective. Therefore, these data may be experimentally obtained or simulated for any precursor, etchant, and/or temperature combination as needed.

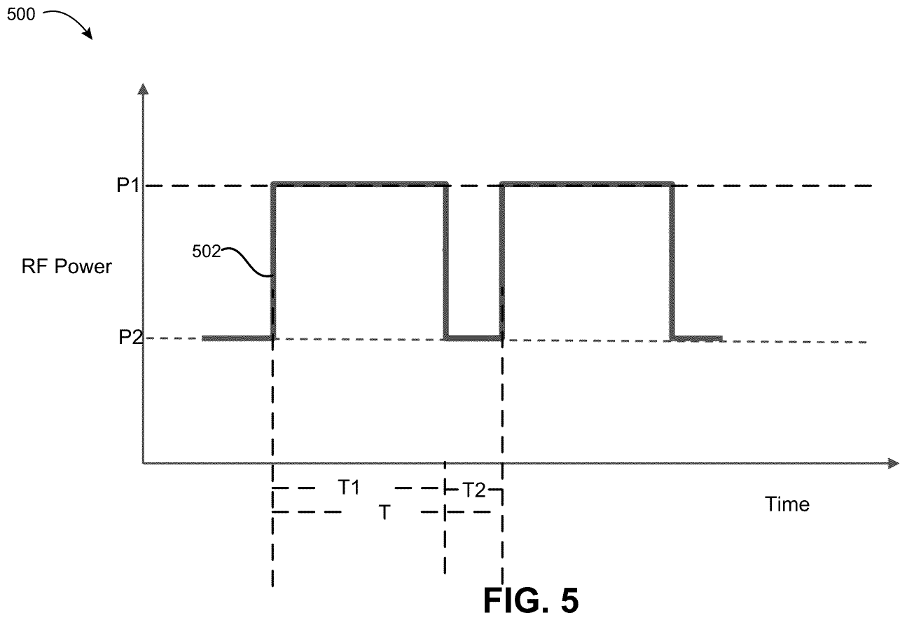

FIG. 5 is a graph 650 of a duty cycle for a gapfill deposition process, according to some embodiments. The gapfill deposition process can be applied to a patterned sample that has features such as trenches or holes of varying dimensions. The graph 500 shows a plot 502 showing a RF power as a function of time. The duty cycle can include a first RF power magnitude, P1, a second RF power magnitude, P2, a period, T, and a frequency (f=1/T). The first power magnitude can be greater than the second power magnitude (e.g., P1>P2). The first power magnitude, P1, can be about 1500 Watts. For example, the first power magnitude can have a value between about 800 Watts and about 900 Watts, between about 900 Watts and 1000 Watts, between about 1000 Watts and about 1100 Watts, between about 1100 Watts and about 1200 Watts, between about 1200 Watts and about 1300 Watts, between about 1300 Watts and about 1400 Watts, between about 1400 Watts and about 1500 Watts, between about 1500 Watts and about 1600 Watts, between about 1600 Watts and about 1700 Watts, between about 1700 Watts and about 1800 Watts, between about 1800 Watts and about 1900 Watts, and/or between about 1900 Watts and about 2000 Watts. The first power magnitude may also be any combination of these ranges (e.g., between about 1200 Watts and about 17000 Watts). The first power magnitude may also be any specific value within these ranges (e.g., about 1500 Watts). In some examples, the first power magnitude can be designed to be a multiplicative factor of the second power magnitude (e.g., P1=1.5*P2, P1=2*P2, etc.).

The second power magnitude, P2, can be about 250 Watts. For example, the first power magnitude can have a value between about 100 Watts and about 150 Watts, between about 150 Watts and 200 Watts, between about 200 Watts and about 250 Watts, between about 250 Watts and about 300 Watts, between about 300 Watts and about 350 Watts, between about 350 Watts and about 400 Watts, between about 400 Watts and about 450 Watts, and/or between about 450 Watts and about 500 Watts. The second power magnitude may also be any combination of these ranges (e.g., between about 200 Watts and about 300 Watts). The second power magnitude may also be any specific value within these ranges (e.g., about 275 Watts).

The frequency, f, of the duty cycle can be about 1000 Hz. For example, the frequency of the duty cycle can have a value between about 50 Hz and about 500 Hz, between about 500 Hz and 1 kHz, between about 1 kHz and about 5 kHz, between about 5 kHz and about 10 kHz, between about 10 kHz and about 50 kHz, between about 50 kHz and about 100 kHz, between about 100 kHz and about 500 kHz, and/or between about 500 kHz and about 1 MHz. The frequency of the duty cycle may also be any combination of these ranges (e.g., between about 500 Hz and about 10 kHz). The second power magnitude may also be any specific value within these ranges (e.g., about 1.2 kHz).

The first power magnitude, P1, can be applied for a time duration T1. Time duration T1 can be more than 50% of the period, T, of the duty cycle. For example, when the frequency of the duty cycle, f, is 1 kHz, then the period is one millisecond and the first power magnitude can be applied for at least half a millisecond. The second power magnitude can be applied for a time duration T2. Time duration T2 can be less than time duration T1. In some examples, time duration T2 can be a percentage of time duration T1. The time duration T2 can be about 50% of the time duration T1. Thus, in the example where the frequency is about 1 kHz, time duration T1 can be about 0.67 milliseconds and time duration T2 can be about 0.33 milliseconds. For example, the time duration T2 can have a value between about 5% of time duration T1 and about 15% of time duration T1, between about 15% of time duration T1 and about 25% of time duration T1, between about 25% of time duration T1 and about 35% of time duration T1, between about 35% of time duration T1 and about 45% of time duration T1, between about 45% of time duration T1 and about 55% of time duration T1, between about 55% of time duration T1 and about 65% of time duration T1, between about 65% of time duration T1 and about 75% of time duration T1, between about 75% of time duration T1 and about 85% of time duration T1, and/or between about 85% of time duration T1 and about 95% of time duration T1. The time duration T2 may also be any combination of these ranges (e.g., between about 5% of time duration T1 and about 95% of time duration T1). The time duration T2 may also be any specific value within these ranges (e.g., about 50% of time duration T1).

The duty cycle can be applied while a patterned sample is in a process chamber, such as process chamber 100 described in FIG. 1. The sample can be maintained at a constant temperature while the duty cycle is applied. The temperature can enhance a creation of free radicals of the gapfill material in the process chamber and encourage deposition of the gapfill material. For example, the gapfill material can be carbon, tungsten, amorphous silicon, etc. The process chamber can include gases that can etch the gapfill material and precursors that can assist in forming deposited layers of the gapfill material. Application of the first power magnitude, P1, during time duration T1 of the duty cycle can effectively both etch and deposit gapfill material. During the application of P1, etchant gases can remove gapfill material from tops of pillars while additional gapfill material can be deposited as sidewall material in trenches. Removing gapfill material from tops of pillars can reduce a likelihood of void formations by avoiding pinch-off occurrences involving overgrowth material. The etchant gases can have a lifetime that enables the etchant gases to remove gapfill material from the tops of pillars without removing gapfill material from sidewalls of trenches. Due to the lifetime, the etchant gases can be absorbed prior to reaching a depth associated with sidewall growth in trenches. During time duration T1, sidewall deposition rates can be dependent on dimensions of trenches. For example, trenches with large diameters can have higher sidewall deposition rates than trenches with smaller diameters.

Application of the second power magnitude, P2, during time duration T2 of the duty cycle can effectively deposit gapfill material without etching gapfill material. The second power magnitude can be less than the first power magnitude, P1. During time duration T2, gapfill material can grow on sidewalls of the trench, on tops of pillars, or both. During time duration T2, sidewall deposition rates can be dependent on dimensions of trenches. For example, trenches with large diameters can have higher sidewall deposition rates than trenches with smaller diameters. The duty cycle can promote a formation of a smooth or flat overgrowth layer above pillars of the patterned sample.

A co-flow rate can be constant during time durations T1 and T2 of the duty cycle. Alternatively, a first co-flow rate can be associated with time duration T1 and a second co-flow rate can be associated with time duration T2. The first co-flow rate can be different than the second co-flow rate. For example, the second co-flow rate can be larger or smaller than the first co-flow rate. Values of P1, P2, T1, T2, the first co-flow rate, or the second co-flow rate can be determined based on a geometry of the patterned sample or on parameters of the gapfill deposition process. The geometry of the patterned sample or the parameters of the gapfill deposition process can include types of shapes of features on the patterned sample, a maximum CD for the features, a minimum CD for the features, a range of CDs, a number of different features, depths of trenches, a target overgrowth layer thickness, a gapfill material, a type of etchant gas used for the duty cycle, a type of precursor, a number of precursors, target sidewall deposition rates, target overgrowth deposition rates, target etching rates, etc.

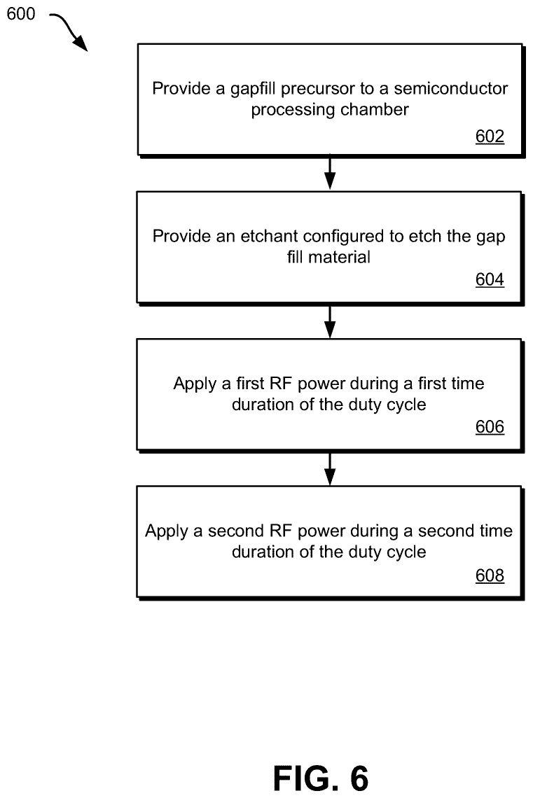

FIG. 6 is a flow chart of an example of a process for depositing material onto a patterned substrate according to some aspects of the present disclosure. The operations of the flowchart start at block 610 and may be performed in the order indicated or in any suitable order. Other examples can involve more operations, fewer operations, different operations, or a different order of the operations shown in FIG. 6. Some or all of the steps of the process 600 can be performed by processors.

At block 602, the process 600 may provide a precursor to a semiconductor processing chamber. The precursor may include precursors for a gapfill material for filling features in a semiconductor structure. The semiconductor structure may include a large memory structure, such as a NAND structure as described above. For example, the semiconductor structure may include alternating oxide/nitride layers that are greater than about 50 layers, greater than about 100 layers, greater than about 200 layers, and so forth. These layers may be assembled in “decks” or stacks that are deposited, etched, then filled with a gapfill material before additional decks are formed on top of existing decks. The overburden after the gapfill process may be planarized to expose the top of the semiconductor structure. The features may include memory holes, slits, trenches, contact holes, and/or other features that may be present in a memory structure. The features may have different feature sizes, such as different critical dimensions. For example, the features may have a height of between about 10 μm and about 30 μm. However, the widths of these features may vary between, for example, 100 nm up to 500 nm.

At block 604, the process 600 may include providing an etchant to the semiconductor processing chamber with the precursor. The etchant may be configured to etch the gapfill material. For example, the etchant may be more selective to the gapfill material than other surfaces exposed on the semiconductor structure. The etchant and the gapfill precursor may be provided simultaneously to the processing chamber. These gases may be provided with a co-flow rate as described above.

The process 600 may include applying RF power to the processing chamber to perform the deposition process. For example, the process 600 may involve depositing material onto a patterned substrate using a process with a cyclic duty cycle. The process can be a PECVD process and the material can be a gapfill material such as carbon, tungsten, amorphous silicon, or any other suitable precursors for various gapfill materials. The duty cycle can be designed to ensure that the gapfill is deposited with a flat overgrowth layer despite a presence of multiple CDs on the patterned substrate. The flat overgrowth layer can have a target maximum (or target minimum) surface roughness. Surface roughness can be described by a variation in a height of the flat overgrowth layer. For example, the overburden of the gapfill material on top of the semiconductor substrate may be substantially uniform (e.g., less than a 5% variation in thickness across the surface).

The RF power may be provided according to a duty cycle. At block 606, a first RF power may be provided during a first time duration of the duty cycle. At block 608, a second RF power may be provided during a second time duration of the duty cycle. The timing of the duty cycle and the RF power levels selected may cause the gapfill material to be deposited in the bottom portion of the features while the gapfill material is simultaneously etched at a top portion of the features during the first time duration. For example, material may be deposited in a bottom 50% of the feature until a pinch off occurs in the bottom of the feature. The “bottom” of the future may then gradually move towards the top of the feature as the gapfill proceeds using a blanket fill pattern. A void may be formed below this pinch off at the bottom of the feature, which is acceptable since it does not risk being exposed when the overburden is planarized off the top of the semiconductor structure and may decrease the time it takes remove the gapfill material. However, as the blanket gapfill proceeds, this process may prevent voids from forming in the top half of the feature that would risk being exposed after planarization.

Application of the first power value can both etch and deposit the gapfill material. During the first time duration, gapfill material can be etched from some surfaces, such top surfaces of pillars, of the patterned sample by an etchant gas. The etchant gas can remove the gapfill material from surfaces of the patterned sample. For example, when the gapfill material is carbon, the etchant gas can be carbon dioxide, hydrogen, ammonia, nitrous oxide, oxygen, some mixture of the aforementioned, etc. Removing gapfill material from tops of pillars can reduce a likelihood of void formations by avoiding pinch-off occurrences involving overgrowth material.

During the first time duration, gapfill material can be deposited and accumulate on some surfaces of the patterned substrate. For example, the gapfill material can be deposited onto sidewalls of trenches of the patterned substrate. The etchant gases can have a lifetime that enables the etchant gases to remove gapfill material from the tops of pillars without removing gapfill material from sidewall formations of trenches. Due to the lifetime, the etchant gases can be absorbed prior to reaching a depth associated with sidewall growth in trenches. During the first time duration, sidewall deposition rates can be dependent on dimensions of trenches. For example, trenches with large diameters can have higher sidewall deposition rates than trenches with smaller diameters.

A first co-flow rate can be applied during the first time duration. Co-flow rate can be a combined flow rate of etchant gas with precursor material present during the PECVD process. Values for the first power value, the first time duration, or the first co-flow rate can be determined based on a geometry of the patterned sample or on parameters of the gapfill deposition process. The geometry of the patterned sample or the parameters of the gapfill deposition process can include types of shapes of features on the patterned sample, a maximum CD for the features, a minimum CD for the features, a range of CDs, a number of different features, depths of trenches, a target overgrowth layer thickness, a gapfill material, a type of etchant gas used for the duty cycle, a type of precursor, a number of precursors, target sidewall deposition rates, target overgrowth deposition rates, target etching rates, etc.

A time dependence of the duty cycle can be similar to plot 602 in graph 600 of FIG. 5. The duty cycle can be cyclical with respect to time and can have a period and a frequency. The duty cycle can be split into a first time duration and a second time duration, so that a sum of the first time duration and the second time duration is equivalent to the period of the duty cycle. In some examples, the first time duration can be greater than 50% of the period and the second time duration can be less than 50% of the period of the duty cycle.

Application of the second RF power can deposit gapfill material on the patterned sample without etching gapfill material from the patterned sample. The second power magnitude can be less than the first power magnitude. During the second time duration, gapfill material can grow on sidewall formations of the trench, on tops of pillars, or both. During the second time duration, sidewall deposition rates can be dependent on dimensions of trenches. For example, trenches with large diameters can have higher sidewall deposition rates than trenches with smaller diameters.

A second co-flow rate can be applied during the second time duration. The second co-flow rate can be different than the first co-flow rate. For example, the second co-flow rate can be greater than the first co-flow rate. Values for the second power value, the second time duration, or the second co-flow rate can be determined based on a geometry of the patterned sample or on parameters of the gapfill deposition process. The geometry of the patterned sample or the parameters of the gapfill deposition process can include types of shapes of features on the patterned sample, a maximum CD for the features, a minimum CD for the features, a range of CDs, a number of different features, depths of trenches, a target overgrowth layer thickness, a gapfill material, a type of etchant gas used for the duty cycle, a type of precursor, a number of precursors, target sidewall deposition rates, target overgrowth deposition rates, target etching rates, etc.

The method 600 may be executed as part of a recipe or other control methodology for controlling the conditions and operations of the semiconductor processing chamber. For example, a controller of the semiconductor processing chamber may include one or more processors, and one or more memory devices (e.g., one or more non-transitory computer-readable media) that store instructions. The instructions may cause the one or more processors to perform the operations of the methods described above.

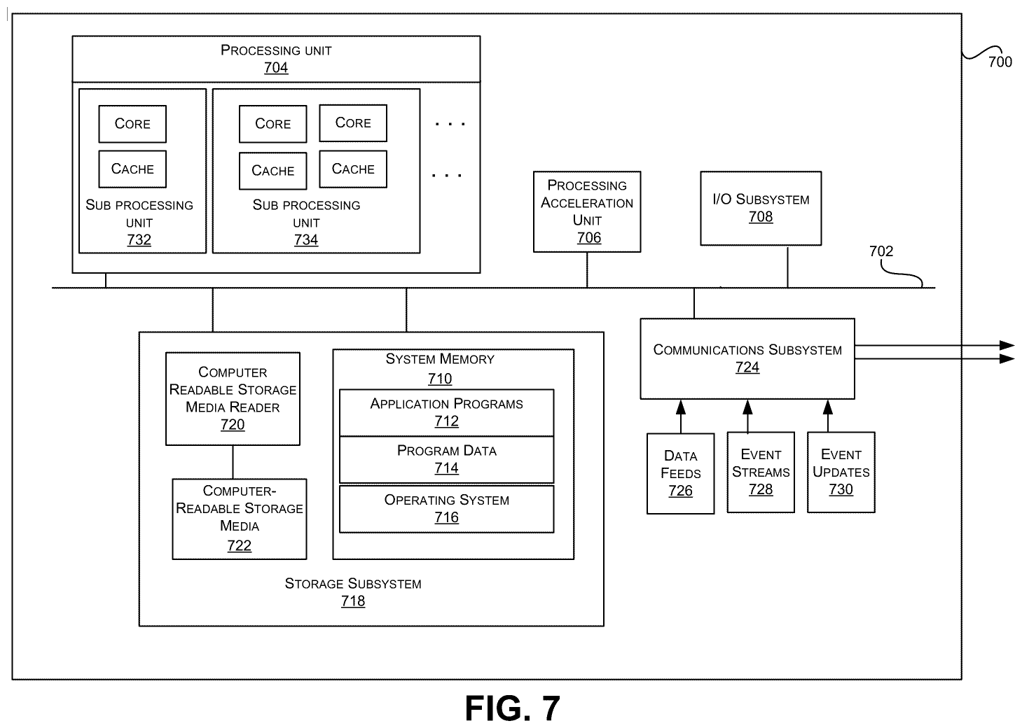

FIG. 7 illustrates an exemplary computer system 700, in which various embodiments may be implemented. The system 700 may be used to implement any of the computer systems described above, such as a controller of the semiconductor processing system. As shown in the figure, computer system 700 includes a processing unit 704 that communicates with a number of peripheral subsystems via a bus subsystem 702. These peripheral subsystems may include a processing acceleration unit 706, an I/O subsystem 708, a storage subsystem 718 and a communications subsystem 724. Storage subsystem 718 includes tangible computer-readable storage media 722 and a system memory 710.

Bus subsystem 702 provides a mechanism for letting the various components and subsystems of computer system 700 communicate with each other as intended. Although bus subsystem 702 is shown schematically as a single bus, alternative embodiments of the bus subsystem may utilize multiple buses. Bus subsystem 702 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 704, which can be implemented as one or more integrated circuits (e.g., a conventional microprocessor or microcontroller), controls the operation of computer system 700. One or more processors may be included in processing unit 704. These processors may include single core or multicore processors. In certain embodiments, processing unit 704 may be implemented as one or more independent processing units 732 and/or 734 with single or multicore processors included in each processing unit. In other embodiments, processing unit 704 may also be implemented as a quad-core processing unit formed by integrating two dual-core processors into a single chip.

In various embodiments, processing unit 704 can execute a variety of programs in response to program code and can maintain multiple concurrently executing programs or processes. At any given time, some or all of the program code to be executed can be resident in processor(s) 704 and/or in storage subsystem 718. Through suitable programming, processor(s) 704 can provide various functionalities described above. Computer system 700 may additionally include a processing acceleration unit 706, which can include a digital signal processor (DSP), a special-purpose processor, and/or the like.

I/O subsystem 708 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 700 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 700 may comprise a storage subsystem 718 that comprises software elements, shown as being currently located within a system memory 710. System memory 710 may store program instructions that are loadable and executable on processing unit 704, as well as data generated during the execution of these programs.

Depending on the configuration and type of computer system 700, system memory 710 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 704. In some implementations, system memory 710 may include multiple different types of memory, such as static random access memory (SRAM) or dynamic random access memory (DRAM). In some implementations, a basic input/output system (BIOS), containing the basic routines that help to transfer information between elements within computer system 700, such as during start-up, may typically be stored in the ROM. By way of example, and not limitation, system memory 710 also illustrates application programs 712, which may include client applications, Web browsers, mid-tier applications, relational database management systems (RDBMS), etc., program data 714, and an operating system 716.

Storage subsystem 718 may also provide a tangible computer-readable storage medium for storing the basic programming and data constructs that provide the functionality of some embodiments. Software (programs, code modules, instructions) that when executed by a processor provide the functionality described above may be stored in storage subsystem 718. These software modules or instructions may be executed by processing unit 704. Storage subsystem 718 may also provide a repository for storing data used in accordance with some embodiments.

Storage subsystem 700 may also include a computer-readable storage media reader 720 that can further be connected to computer-readable storage media 722. Together and, optionally, in combination with system memory 710, computer-readable storage media 722 may comprehensively represent remote, local, fixed, and/or removable storage devices plus storage media for temporarily and/or more permanently containing, storing, transmitting, and retrieving computer-readable information.

Computer-readable storage media 722 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 700.

By way of example, computer-readable storage media 722 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 722 may include, but is not limited to, flash memory cards, universal serial bus (USB) flash drives, secure digital (SD) cards, DVD disks, digital video tape, and the like. Computer-readable storage media 722 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 700.

Communications subsystem 724 provides an interface to other computer systems and networks. Communications subsystem 724 serves as an interface for receiving data from and transmitting data to other systems from computer system 700. For example, communications subsystem 724 may enable computer system 700 to connect to one or more devices via the Internet. In some embodiments communications subsystem 724 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 724 can provide wired network connectivity (e.g., Ethernet) in addition to or instead of a wireless interface.

In some embodiments, communications subsystem 724 may also receive input communication in the form of structured and/or unstructured data feeds 726, event streams 728, event updates 730, and the like on behalf of one or more users who may use computer system 700.

Additionally, communications subsystem 724 may also be configured to receive data in the form of continuous data streams, which may include event streams 728 of real-time events and/or event updates 730, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 724 may also be configured to output the structured and/or unstructured data feeds 726, event streams 728, event updates 730, and the like to one or more databases that may be in communication with one or more streaming data source computers coupled to computer system 700.

Computer system 700 can be one of various types, including a handheld portable device (e.g., a smartphone, a computing tablet, a PDA), a PC, a workstation, a mainframe, a kiosk, a server rack, or any other data processing system.

Due to the ever-changing nature of computers and networks, the description of computer system 700 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method comprising:
providing a precursor to a semiconductor processing chamber, wherein the precursor comprises a gapfill material for filling features in a semiconductor structure, and the features in the semiconductor structure have different critical dimensions (CDs);
providing an etchant to the semiconductor processing chamber with the precursor, wherein the etchant is configured to etch the gapfill material;
applying a radio-frequency (RF) power to the processing chamber to perform a deposition process, wherein the RF power is provided according to a duty cycle comprising:
a first RF power provided during a first time duration; and
a second RF power provided during a second time duration, wherein the second RF power is less than the first RF power.

2. The method of claim 1, wherein the semiconductor structure comprises a memory structure comprising more than 100 alternating oxide/nitride layers.

3. The method of claim 1, wherein the first time duration is greater than 50% of the period of the duty cycle.

4. The method of claim 1, wherein the precursor comprises carbon, tungsten, or amorphous silicon.

5. The method of claim 1, further comprising providing a co-flow rate to the processing chamber while performing the deposition process, wherein the co-flow rate is provided according to the duty cycle comprising:
a first co-flow rate during the first time duration; and
a second co-flow rate during the second time duration, wherein the second co-flow rate is greater than the first co-flow rate.

6. The method of claim 1, wherein applying the first RF power comprises etching tops of pillars of the semiconductor structure while depositing the material on sidewall formations of trenches of the patterned sample.

7. The method of claim 1, wherein applying the second RF power comprises depositing the material onto tops of pillars of the patterned sample while depositing the material on sidewall formations of trenches of the patterned sample.

8. A method comprising:
providing a precursor to a semiconductor processing chamber, wherein the precursor comprises a gapfill material for filling features in a semiconductor structure, and the features in the semiconductor structure have different critical dimensions (CDs);
providing an etchant to the semiconductor processing chamber with the precursor, wherein the etchant is configured to etch the gapfill material;
applying a radio-frequency (RF) power to the processing chamber to perform a deposition process, wherein the RF power is provided according to a duty cycle comprising:
a first RF power provided during a first time duration during which the gapfill material is deposited in a bottom portion of the features while the gapfill material is etched at a top portion of the features; and
a second RF power provided during a second time duration during which the gapfill material is deposited in the bottom portion of the features at the top portion of the features.

9. The method of claim 8, wherein the features in the semiconductor structure comprise memory holes with a CD that is less than 150 nm.

10. The method of claim 8, wherein the features in the semiconductor structure comprise slits with a CD that is grater than 350 nm.

11. The method of claim 8, wherein the features comprise first features and second features, and the second features have a CD that is at least twice as large as a CD of the first features.

12. The method of claim 11, wherein the first RF power results in a higher deposition rate in the first features and a lower deposition rate in the second features.

13. The method of claim 11, wherein the second RF power results in a similar deposition rate in the first features and the second features.

14. The method of claim 11, further comprising:
selecting the first RF power from a first data set for a first feature size and a second data set from a second feature size, wherein the first data set and the second data set represent deposition rates over an RF power range, and the first RF power corresponds to a similar deposition rate in both the first data set and the second data set.

15. The method of claim 11, further comprising:
selecting the second RF power from a first data set for a first feature size and a second data set from a second feature size, wherein the first data set and the second data set represent deposition rates over an RF power range, and the second RF power corresponds to a low deposition rate in the first data set and to a higher deposition rate in the second data set.

16. A method comprising:
providing a precursor to a semiconductor processing chamber, wherein the precursor comprises a gapfill material for filling features in a semiconductor structure, and the features in the semiconductor structure have different critical dimensions (CDs);
providing an etchant to the semiconductor processing chamber with the precursor, wherein the etchant is configured to etch the gapfill material;
applying a radio-frequency (RF) power to the processing chamber to perform a deposition process, wherein the RF power is provided according to a duty cycle comprising:
a first RF power provided during a first time duration; and
a second RF power provided during a second time duration, wherein the duty cycle causes the features in the semiconductor structure having different CDs to finish the gapfill process at approximately a same time and an overburden of the gapfill material on top of the semiconductor structure is substantially uniform.

17. The method of claim 16, wherein the duty cycle causes the features in the semiconductor structure having different CDs to finish the gapfill process without voids in top halves of the features.

18. The method of claim 16, wherein the duty cycle causes the features in the semiconductor structure having different CDs to finish the gapfill process to form voids in bottom halves of the features.

19. The method of claim 16, wherein the duty cycle comprises a square wave that oscillates between the first RF power and the second RF power, and the first RF power comprises between 50 and 90% of each cycle.

20. The method of claim 16, wherein:
the first RF power comprises between about 800 W and about 2000 W; and
the second RF power comprises between about 100 W and about 500 W.
